(19) United States
(12) Patent Application Publication
(10) Pub. No.: US 2025/0364909 A1
(43) Pub. Date: Nov. 27, 2025

(54) POWER SUPPLY CIRCUIT

(71) Applicant: Pu-Dan Limited Corp., New Taipei City (TW)

(72) Inventor: Wei-Chih HUANG, New Taipei City (TW)

(21) Appl. No.: 19/200,758

(22) Filed: May 7, 2025

(30) Foreign Application Priority Data
May 23, 2024 (TW) 113119093

(51) Int. Cl. H02M 3/155

(52) U.S. Cl. CPC H02M 3/155

(57) ABSTRACT

A power supply circuit providing power to a system on chip (SOC) is provided. A power generation circuit adjusts the input voltage according to the first feedback voltage to generate an output voltage. A first feedback circuit is coupled to the power generation circuit and generates the first feedback voltage according to the output voltage. A conducting wire is coupled between the power generation circuit and the SOC to receive the output voltage. The conducting wire uses the output voltage as a load voltage and provides the load voltage to the SOC. A second feedback circuit generates a second feedback voltage according to the load voltage. A compensation circuit adjusts the first feedback voltage according to the second feedback voltage. In response to the second feedback voltage being higher than a first reference voltage, the compensation circuit increases the first feedback voltage.

### CROSS REFERENCE TO RELATED APPLICATIONS

This application claims priority of Taiwan Patent Application No. 113119093, filed on May 23, 2024, the entirety of which is incorporated by reference herein.

### BACKGROUND OF THE INVENTION

### Field of the Invention

The invention relates to a power supply circuit, and more particularly it relates to a power supply circuit having two feedback circuits.

### Description of the Related Art

The electronic products commonly used in daily life need power to drive the electronic circuits integrated therein. The quality of the power can affect the performance of these electronic circuits. However, signals can easily interfered with the power. Furthermore, the voltage drops and ripple voltage caused by the impedance of the printed circuit boards of the electronic products can also affect the power level, thereby affecting the overall performance of the electronic circuits.

### BRIEF SUMMARY OF THE INVENTION

In accordance with an embodiment, a power supply circuit provides power to a system on chip (SOC) and comprises a power generation circuit, a first feedback circuit, a conducting wire, a second feedback circuit, and a compensation circuit. The power generation circuit adjusts an input voltage according to a first feedback voltage to generate an output voltage. The first feedback circuit is coupled to the power generation circuit and generates the first feedback voltage according to the output voltage. The conducting wire is coupled between the power generation circuit and the SOC to receive the output voltage, uses the output voltage as a load voltage and provides the load voltage to the SOC. The second feedback circuit is coupled to the conducting wire and generates a second feedback voltage according to the load voltage. The compensation circuit adjusts the first feedback voltage according to the second feedback voltage and comprises an operational amplifier, a first resistor, a second resistor, and a third resistor. The operational amplifier comprises a non-inverting input terminal, an inverting input terminal and an output terminal. The non-inverting input terminal receives the second feedback voltage. The inverting terminal is coupled to a node. The first resistor is coupled between the output terminal and the node. The second resistor is coupled between the node and a ground terminal. The third resistor is coupled between the output terminal and the first feedback circuit. In response to the second feedback voltage being higher than a first reference voltage, the compensation circuit increases the first feedback voltage. In response to the first feedback voltage being higher than a second reference voltage, the power generation circuit reduces the output voltage. In response to the second feedback voltage being lower than the first reference voltage, the compensation circuit reduces the first feedback voltage. In response to the first feedback voltage being lower than the second reference voltage, the power generation circuit increases the output voltage.

In accordance with another embodiment, a power supply circuit provides power to a system on chip (SOC) and comprises a power generation circuit, a first feedback circuit, a conducting wire, a second feedback circuit, and a compensation circuit. The power generation circuit adjusts an input voltage according to a first feedback voltage to generate an output voltage. The first feedback circuit is coupled to the power generation circuit and generates the first feedback voltage according to the output voltage. The conducting wire is coupled between the power generation circuit and the SOC to receive the output voltage, uses the output voltage as a load voltage and provides the load voltage to the SOC. The second feedback circuit is coupled to the conducting wire and generates a second feedback voltage according to the load voltage. The compensation circuit adjusts the first feedback voltage according to the second feedback voltage and comprises an analog-to-digital converter, a processing circuit, a digital-to-analog converter, and a resistor. The analog-to-digital converter converts the second feedback voltage to generate a digital signal. The processing circuit calculates a difference value, which is the value of the difference between the digital signal and a predetermined value and outputs the difference value. The digital-to-analog converter converts the difference value to generate an analog signal. The resistor is coupled between the digital-to-analog converter and the first feedback circuit and receives the analog signal.

In accordance with another embodiment, a power supply circuit providing power to a system on chip (SOC) and comprises a power generation circuit, a first feedback circuit, a conducting wire, a second feedback circuit, and a compensation circuit. The power generation circuit adjusts an input voltage according to a first feedback voltage to generate an output voltage. The first feedback circuit is coupled to the power generation circuit and generates the first feedback voltage according to the output voltage. The conducting wire is coupled between the power generation circuit and the SOC to receive the output voltage, uses the output voltage as a load voltage and provides the load voltage to the SOC. The second feedback circuit is coupled to the conducting wire and generates a second feedback voltage according to the load voltage. The compensation circuit adjusts the first feedback voltage according to the second feedback voltage and comprises an operational amplifier, an inverter, a first resistor, a second resistor, and a third resistor. The operational amplifier comprises a non-inverting input terminal, an inverting input terminal, and a first output terminal. The inverting input terminal receives the second feedback voltage. The non-inverting input terminal is coupled to a node. The inverter comprises an input terminal and a second output terminal. The input terminal is coupled to the first output terminal. The first resistor is coupled between the second output terminal and the node. The second resistor is coupled between the node and a ground terminal. The third resistor is coupled between the second output terminal and the first feedback circuit. In response to the second feedback voltage being higher than a first reference voltage, the compensation circuit increases the first feedback voltage. In response to the first feedback voltage being higher than a second reference voltage, the power generation circuit reduces the output voltage. In response to the second feedback voltage being lower than the first reference voltage, the compensation circuit reduces the first feedback voltage. In response to the first feedback voltage being lower than the second reference voltage, the power generation circuit increases the output voltage.

### BRIEF DESCRIPTION OF THE DRAWINGS

The present invention can be more fully understood by reading the subsequent detailed description and examples with references made to the accompanying drawings, wherein:

FIG. 1 is a schematic diagram of an exemplary embodiment of a power supply system according to various aspects of the present disclosure.

FIG. 2 is a schematic diagram of an exemplary embodiment of a compensation circuit according to various aspects of the present disclosure.

FIG. 3 is a schematic diagram of another exemplary embodiment of the compensation circuit according to various aspects of the present disclosure.

FIG. 4 is a schematic diagram of another exemplary embodiment of the compensation circuit according to various aspects of the present disclosure.

### DETAILED DESCRIPTION OF THE INVENTION

The present invention will be described with respect to particular embodiments and with reference to certain drawings, but the invention is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the invention.

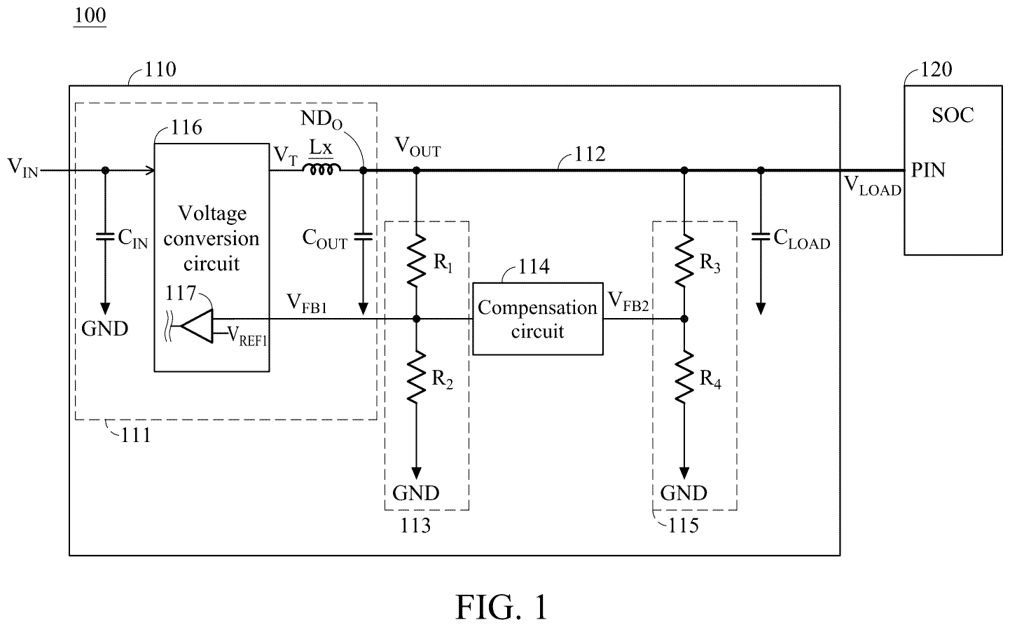

FIG. 1 is a schematic diagram of an exemplary embodiment of a power supply system according to various aspects of the present disclosure. As shown in FIG. 1, the power supply system 100 comprises a power supply circuit 110 and a system on chip (SOC) 120. The power supply circuit 110 provides power to the SOC 120 to drive the SOC 120. In this embodiment, the power supply circuit 110 comprises a power generation circuit 111, a conducting wire 112, feedback circuits 113 and 115, and a compensation circuit 114. The power generation circuit 111 adjusts the input voltage V_{IN} to generate an output voltage V_{OUT}.

The structure of the power generation circuit 111 is not limited in the present disclosure. In one embodiment, the power generation circuit 111 is a boost converter circuit. The power generation circuit 111 increases the input voltage V_{IN}, and the increased voltage serves as the output voltage V_{OUT}. In this case, the output voltage V_{OUT} is higher than the input voltage V_{IN}. In another embodiment, the power generation circuit 111 is a buck converter circuit. The power generation circuit 111 reduces the input voltage V_{IN}, and the reduced voltage serves as the output voltage V_{OUT}. In this case, the output voltage V_{OUT} is lower than the input voltage V_{IN}. In other embodiments, the power generation circuit 111 is a regulator to stabilize the output voltage V_{OUT}. In this case, the output voltage V_{OUT} is lower than the input voltage V_{IN}.

In this embodiment, the power generation circuit 111 further adjusts the output voltage V_{OUT} according to a feedback voltage V_{FB1}. For example, when the feedback voltage V_{FB1} is lower than a reference voltage V_{REF1} (or referred to as a second reference voltage), this indicates that the output voltage V_{OUT} may be lower than a first predetermined value, such as 3V. Therefore, the power generation circuit 111 increases the output voltage V_{OUT}. When the feedback voltage V_{FB1} is higher than the reference voltage V_{REF1}, this indicates that the output voltage V_{OUT} may be higher than the first predetermined value, such as 3V. Therefore, the power generation circuit 111 reduces the output voltage V_{OUT}.

In one embodiment, the power generation circuit 111 comprises an input capacitor C_{IN}, a voltage conversion circuit 116, an inductor Lx, and an output capacitor C_{OUT}, but the disclosure is not limited thereto. In this embodiment, the voltage conversion circuit 116 receives the input voltage V_{IN} and is coupled to the input capacitor C_{IN}. The voltage conversion circuit 116 adjusts the input voltage V_{IN} according to the feedback voltage V_{FB1} to generate a converted voltage V_{T}. The structure of the voltage conversion circuit 116 is not limited in the present disclosure. In one embodiment, the voltage conversion circuit 116 comprises an operational amplifier 117. The operational amplifier 117 may be used as a comparator.

When the feedback voltage V_{FB1} is higher than a reference voltage V_{REF1}, the operational amplifier 117 may output a first level, such as a low level. The voltage conversion circuit 116 adjusts (e.g., to reduce) the converted voltage V_{T} according to the output of the operational amplifier 117. When the feedback voltage V_{FB1} is lower than the reference voltage V_{REF1}, the operational amplifier 117 may output a second level, such as a high level. The voltage conversion circuit 116 adjusts (e.g., to increase) the converted voltage V_{T} according to the output of the operational amplifier 117. The voltage conversion circuit 116 outputs the converted voltage V_{T} to control the charge operations and the discharge operations of the inductor Lx and the output capacitor C_{OUT} so that the output node ND_{O} provides the output voltage V_{OUT}.

As shown in FIG. 1, the inductor Lx is coupled between the voltage conversion circuit 116 and the output node ND_{O}. The output capacitor C_{OUT} is coupled between the output node ND_{O} and a ground terminal GND. In this embodiment, the output node ND_{O} is the output terminal of the power generation circuit 111. The voltage of the output node ND_{O} is referred to as the output voltage V_{OUT}.

The present disclosure does not limit how the voltage conversion circuit 116 adjusts the converted voltage V_{T} according to the feedback voltage V_{FB1}. In one embodiment, when the feedback voltage V_{FB1} is higher than the reference voltage V_{REF1}, the voltage conversion circuit 116 reduces the converted voltage V_{T}. When the feedback voltage V_{FB1} is lower than the reference voltage V_{REF1}, the voltage conversion circuit 116 increases the converted voltage V_{T}.

The feedback circuit 113 is coupled to the power generation circuit 111 and generates the feedback voltage V_{FB1} according to the output voltage V_{OUT}. In one embodiment, the feedback circuit 113 is a voltage-division circuit which divides the output voltage V_{OUT} to generate the feedback voltage V_{FB1}. In this embodiment, the feedback circuit 113 comprises resistors R₁ and R₂. The resistor R₁ is connected to the resistor R₂ in series between the output node ND_{O} and the ground terminal GND.

The conducting wire 112 is coupled between the power generation circuit 111 and the SOC 120 to transmit the output voltage V_{OUT} to the power input pin PIN of the SOC 120. In this embodiment, the conducting wire 112 uses the output voltage V_{OUT} as a load voltage V_{LOAD} and provides the load voltage V_{LOAD} to the power input pin PIN of the SOC 120 to drive the SOC 120. In this case, the load voltage V_{LOAD} is the voltage actually received by the SOC 120 and serves as the operation voltage of the SOC 120. In some embodiments, the equivalent resistance of the conducting wire 112 causes a voltage drop, so that the load voltage V_{LOAD} may be lower than the output voltage V_{OUT}.

The feedback circuit 115 is coupled to the conducting wire 112 and generates a feedback voltage V_{FB2} according to the load voltage V_{LOAD}. In one embodiment, the feedback circuit 115 is a voltage-division circuit which divides the load voltage V_{LOAD} to generate the feedback voltage V_{FB2}. The level of the feedback voltage V_{FB2} is not limited in the present disclosure. The feedback voltage V_{FB2} may be higher or lower than the feedback voltage V_{FB1}. In one embodiment, the feedback voltage V_{FB2} may be 0.4V, and the feedback voltage V_{FB1} may be 0.8V.

In this embodiment, the feedback circuit 115 comprises resistors R₃ and R₄. The resistor R₃ is connected to the resistor R₄ in series between the power input pin PIN of the SOC 120 and the ground terminal GND. In some embodiments, the feedback circuit 115 is close to one end of the conducting wire 112 (i.e., the end of the conducting wire 112 close to the SOC 120), and the feedback circuit 113 is close to the other end of the conducting wire 112 (i.e., the end of the conducting wire 112 close to the power generation circuit 111). Since the feedback circuit 115 is closer to the SOC 120 than the feedback circuit 113, the feedback voltage V_{FB2} generated by the feedback circuit 115 can better reflect the variation of the load voltage V_{LOAD}.

The compensation circuit 114 adjusts the feedback voltage V_{FB1} according to the feedback voltage V_{FB2}. For example, when the feedback voltage V_{FB2} is too high, it means that the output voltage V_{OUT} is too high. Therefore, the compensation circuit 114 increases the feedback voltage V_{FB1}, so that the power generation circuit 111 reduces the output voltage V_{OUT}. When the feedback voltage V_{FB2} is too low, it means that the output voltage V_{OUT} is too low. Therefore, the compensation circuit 114 reduces the feedback voltage V_{FB1}, so that the power generation circuit 111 increases the output voltage V_{OUT}.

Due to the equivalent resistance of the conducting wire 112, when the conducting wire 112 transmits the output voltage V_{OUT} to the power input pin PIN of the SOC 120, the voltage (i.e., the load voltage V_{LOAD}) actually received by the power input pin PIN may be lower than the output voltage V_{OUT}. However, since the feedback circuit 115 is closer to the SOC 120 than the feedback circuit 113, the feedback voltage V_{FB2} generated by the feedback circuit 115 can better reflect the variation of the load voltage V_{LOAD}. The compensation circuit 114 appropriately adjusts the feedback voltage V_{FB1} according to the variation of the feedback voltage V_{FB2}, thereby enabling the power generation circuit 111 to adjust the output voltage V_{OUT} to compensate for the voltage drop of the load voltage V_{LOAD} caused by the equivalent resistance of the conducting wire 112.

By adjusting the feedback voltage V_{FB1} by the compensation circuit 114, the voltage drop caused by the conducting wire 112 can be compensated, and the voltage error value caused by the layout of the printed circuit board (PCB) can be reduced, thereby improving the power quality of the power generation circuit 111. In some embodiments, the load voltage V_{LOAD} may be higher or lower than the reference voltage V_{REF1}.

Additionally, for chips manufactured using advanced manufacturing processes, the ripple component of the load voltage V_{LOAD} must be lower than 2% of a core voltage. For example, if the load voltage V_{LOAD} is 0.6V, the ripple voltage must be lower 10 mV. However, due to noise interference, the SOC 120 may receive a ripple voltage higher than 20 mV. In this case, since the compensation circuit 114 adjusts the feedback voltage V_{FB1} according to the feedback voltage V_{FB2} and the feedback voltage V_{FB2} reflects the ripple voltage, the compensation circuit 114 can also compensate for the voltage fluctuation caused by the ripple voltage. Since the compensation circuit 114 stabilizes the quality of the load voltage V_{LOAD}, the performance of the SOC 120 can be ensured.

In other embodiments, since the feedback circuit 113 is close to the power generation circuit 111, the feedback voltage V_{FB1} generated by the feedback circuit 113 can reflect the variation of the output voltage V_{OUT}. Therefore, the voltage conversion circuit 116 stabilizes the output voltage V_{OUT} at a first predetermined value, such as 3V, according to the feedback voltage V_{FB1}.

The two-stage feedback control stabilizes the level of the output voltage V_{OUT}. The two-stage feedback control can also adjust the output voltage V_{OUT} in real time by adjusting the feedback voltage V_{FB1} when the load voltage V_{LOAD} changes, thereby maintaining the quality of the load voltage V_{LOAD} and stabilizing the performance of the SOC 120.

In some embodiments, the power generation circuit 111 further comprises a load capacitor C_{LOAD}. The load capacitor C_{LOAD} is connected to the feedback circuit 115 in parallel and close to the power input pin PIN of the SOC 120. In some embodiments, the compensation circuit 114 is integrated into the SOC 120. In this case, the SOC 120 further comprises an input pin (now shown) which is coupled to the feedback circuit 115 to receive the feedback voltage V_{FB2}. The SOC 120 further comprises an output pin (not shown) which is coupled to the feedback circuit 113 to adjust the feedback voltage V_{FB1}.

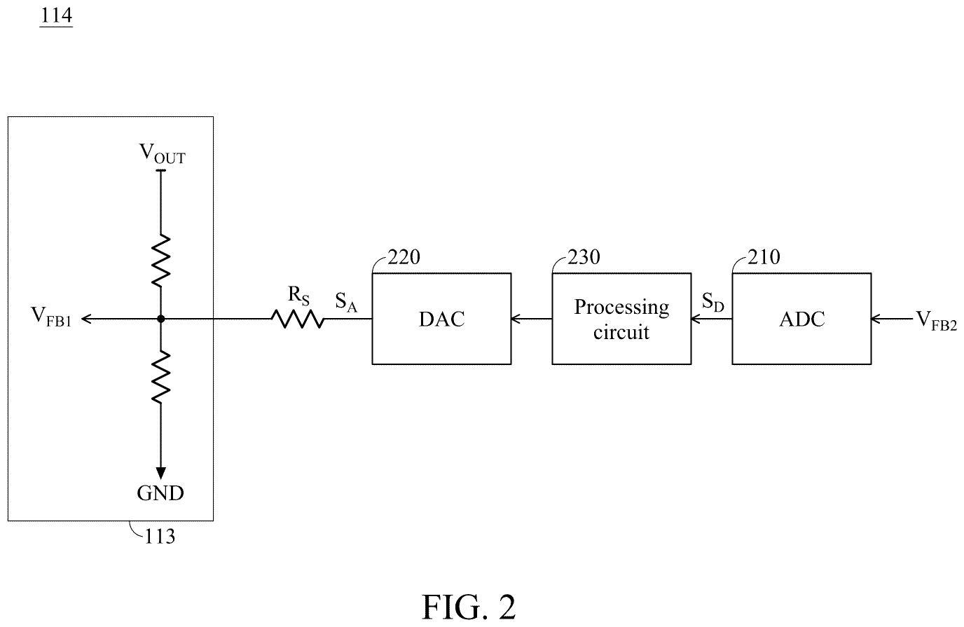

FIG. 2 is a schematic diagram of an exemplary embodiment of the compensation circuit according to various aspects of the present disclosure. The compensation circuit 114 comprises an analog-to-digital converter (ADC) 210, a digital-to-analog converter (DAC) 220, a processing circuit 230, and a resistor R_{S}. The ADC 210 converts the feedback voltage V_{FB2} to a digital signal S_{D}. The feedback voltage V_{FB2} is in an analog format. The digital signal S_{D} is in a digital format. The processing circuit 230 calculates the difference value, which is the value of the difference between the digital signal S_{D} and a second predetermined value, and provides the difference value to the DAC 220. The structure of the processing circuit 230 is not limited in the present disclosure. In one embodiment, the processing circuit 230 comprises a central processing unit (CPU), a micro-controller (MCU) or a digital signal processor (DSP).

The DAC 220 converts the difference value output from the processing circuit 230 to generate an analog signal S_{A}. The difference value is in a digital format. The analog signal S_{A} is in an analog format. The resistor R_{S} is coupled between the DAC 220 and the feedback circuit 113 and receives the analog signal S_{A}. In one embodiment, the DAC 220 is a current DAC (iDAC). By outputting (source) current to the feedback circuit 113 or extracting (sink) current from the feedback circuit 113, the purpose of adjusting the feedback voltage V_{FB1} is achieved. For example, when the DAC 220 outputs current to the feedback circuit 113, the feedback voltage V_{FB1} is increased. When the DAC 220 extracts the current from the feedback circuit 113, the feedback voltage V_{FB1} is reduced.

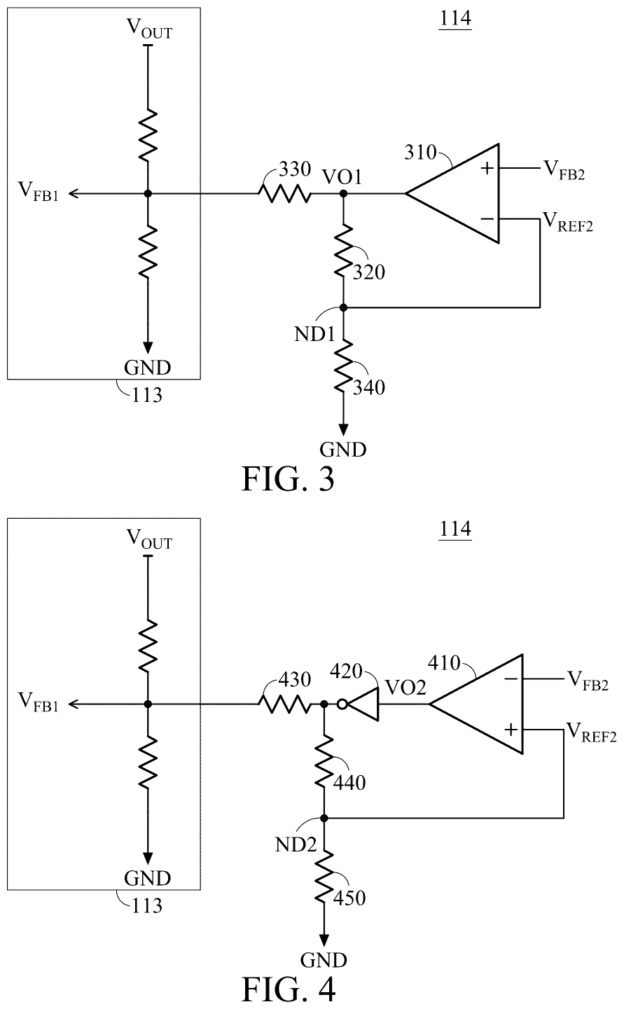

FIG. 3 is a schematic diagram of another exemplary embodiment of the compensation circuit according to various aspects of the present disclosure. The compensation circuit 114 comprises an operational amplifier 310 and resistors 320, 330, and 340. The non-inverting input terminal of the operational amplifier 310 receives the feedback voltage V_{FB2}. The inverting input terminal of the operational amplifier 310 is coupled to a node ND1 to receive a reference voltage V_{REF2} (or referred to as a first reference voltage). The resistor 330 is coupled between the output terminal of the operational amplifier 310 and the feedback circuit 113. In one embodiment, the resistance of the resistor 330 may be 02. In another embodiment, the resistor 330 can be omitted.

The resistor 320 is coupled between the output terminal of the operational amplifier 310 and the node ND1. The resistor 340 is coupled between the node ND1 and the ground terminal GND. In this embodiment, the resistors 320 and 340 constitute a voltage-division circuit and generate the reference voltage V_{REF2} according to the output of the operational amplifier 310. In some embodiments, the reference voltage V_{REF2} is lower than the reference voltage V_{REF1} of the voltage conversion circuit 116.

In this embodiment, the operational amplifier 310 generates an output difference voltage VO1 according to the difference value, which is the value of the difference between the feedback voltage V_{FB2} and the reference voltage V_{REF2}. When the feedback voltage V_{FB2} is higher than the reference voltage V_{REF2}, the output difference voltage VO1 is a positive difference voltage. When the feedback voltage V_{FB2} is lower than the reference voltage V_{REF2}, the output difference voltage VO1 is a negative difference voltage. In this embodiment, the operational amplifier 310 detects the difference value, which is the value of the difference between the feedback voltage V_{FB2} and the reference voltage V_{REF2}, to adjust the feedback voltage V_{FB1}.

For example, when the feedback voltage V_{FB2} is higher than the reference voltage V_{REF2}, since the output difference voltage VO1 is a positive difference voltage, the current passing through the resistor 330 and entering the feedback circuit 113 increases. Therefore, the feedback voltage V_{FB1} is increased. When the feedback voltage V_{FB2} is lower than the reference voltage V_{REF2}, since the output difference voltage VO1 is a negative difference voltage, the current flowing into the resistor 330 from the feedback circuit 113 increases. Therefore, the feedback voltage V_{FB1} is reduced.

In other embodiments, the operational amplifier 310 is used to provide a current to the feedback circuit 113 or to extract a current from the feedback circuit 113 so that the feedback voltage V_{FB1} is changed. For example, when the operational amplifier 310 outputs a current to the feedback circuit 113, the feedback voltage V_{FB1} is increased. When the operational amplifier 310 extracts a current from the feedback circuit 113, the feedback voltage V_{FB1} is reduced.

In some embodiments, the operational amplifier 310 is disposed near the power input pin PIN of the SOC 120 to detect the variation of the load voltage V_{LOAD}, dynamically adjust the current entering the feedback circuit 113, and adjust the output voltage V_{OUT} in real time so that the variation of the load voltage V_{LOAD} is compensated. Additionally, the operational amplifier 310 determines whether the ripple voltage of the load voltage V_{LOAD} is too high according to the variation of the feedback voltage V_{FB2}, and controls the current entering the feedback circuit 113 according to the ripple voltage to adjust the output voltage V_{OUT} and compensate for the influence caused by the ripple voltage.

Furthermore, the operational amplifier 310 determines whether the load voltage V_{LOAD} is affected by an excessive voltage drop caused by the current flowing through the conducting wire 112 according to the variation of the feedback voltage V_{FB2}. When the level of the load voltage V_{LOAD} changes too much, the operational amplifier 310 controls the current entering the feedback circuit 113 according to the voltage drop caused by the conducting wire 112, thereby adjusting the output voltage V_{OUT} to compensate for the voltage drop of the load voltage V_{LOAD} caused by the current flowing through the conducting wire 112.

FIG. 4 is a schematic diagram of another exemplary embodiment of the compensation circuit according to various aspects of the present disclosure. The compensation circuit 114 comprises an operational amplifier 410, an inverter 420, and resistors 430, 440, and 450. The non-inverting input terminal of the operational amplifier 410 is coupled to the node ND2 to receive the reference voltage V_{REF2}. The inverting input terminal of the operational amplifier 410 receives the feedback voltage V_{FB2}. The input terminal of the inverter 420 is coupled to the output terminal of the operational amplifier 410.

The resistor 430 is coupled between the output terminal of the inverter 420 and the feedback circuit 113. In one embodiment, the resistor 430 may be 0Ω. In another embodiment, the resistor 430 can be omitted. The resistor 440 is coupled between the output terminal of the inverter 420 and the node ND2. The resistor 450 is coupled between the node ND2 and the ground terminal GND. In this embodiment, the resistors 440 and 450 constitute a voltage-division circuit to process the output of the inverter 420, and the processed voltage serves as the reference voltage V_{REF2}.

In this embodiment, the operational amplifier 410 generates the output difference voltage VO2 according to the difference value, which is the value of the difference between the feedback voltage V_{FB2} and the reference voltage V_{REF2}. When the feedback voltage V_{FB2} is higher than the reference voltage V_{REF2}, the output difference voltage VO2 is a negative difference voltage. The inverter 420 inverts the output difference voltage VO2 to provide a positive difference voltage. At this time, the current passing through the resistor 430 and entering the feedback circuit 113 increases. Therefore, the feedback voltage V_{FB1} is increased. When the feedback voltage V_{FB2} is lower than the reference voltage V_{REF2}, the output difference voltage VO2 is a positive difference voltage. The inverter 420 inverts the output difference voltage VO2 and outputs a negative difference voltage. At this time, current flows to the resistor 430 from the feedback circuit 113. Therefore, the feedback voltage V_{FB1} is reduced.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will be understood that although the terms “first,” “second,” etc. may be used herein to describe various elements, these elements should not be limited by these terms. These terms are only used to distinguish one element from another. In the following claims, the terms “first,” “second,” etc. are used merely as labels, and are not intended to impose numerical requirements on their objects.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). For example, it should be understood that the system, device and method may be realized in software, hardware, firmware, or any combination thereof. Therefore, the scope of the appended claims should be accorded the broadest interpretation so as to encompass all such modifications and similar arrangements.

What is claimed is:

1. A power supply circuit providing power to a system on chip (SOC), comprising:
a power generation circuit adjusting an input voltage according to a first feedback voltage to generate an output voltage;
a first feedback circuit coupled to the power generation circuit and generating the first feedback voltage according to the output voltage;
a conducting wire coupled between the power generation circuit and the SOC to receive the output voltage, using the output voltage as a load voltage and providing the load voltage to the SOC;
a second feedback circuit coupled to the conducting wire and generating a second feedback voltage according to the load voltage; and
a compensation circuit adjusting the first feedback voltage according to the second feedback voltage and comprising:
an operational amplifier comprising a non-inverting input terminal, an inverting input terminal and an output terminal, wherein the non-inverting input terminal receives the second feedback voltage, and the inverting terminal is coupled to a node;
a first resistor coupled between the output terminal and the node;
a second resistor coupled between the node and a ground terminal; and
a third resistor coupled between the output terminal and the first feedback circuit,
wherein:
in response to the second feedback voltage being higher than a first reference voltage, the compensation circuit increases the first feedback voltage,
in response to the first feedback voltage being higher than a second reference voltage, the power generation circuit reduces the output voltage,
in response to the second feedback voltage being lower than the first reference voltage, the compensation circuit reduces the first feedback voltage,
in response to the first feedback voltage being lower than the second reference voltage, the power generation circuit increases the output voltage.

2. The power supply circuit as claimed in claim 1, wherein the second feedback circuit is closer to the SOC than the first feedback circuit.

3. The power supply circuit as claimed in claim 1, wherein:
the first feedback circuit is a first voltage-division circuit which divides the output voltage to generate the first feedback voltage, and
the second feedback circuit is a second voltage-division circuit which divides the load voltage to generate the second feedback voltage.

4. The power supply circuit as claimed in claim 1, wherein the first reference voltage is lower than the second reference voltage.

5. The power supply circuit as claimed in claim 1, wherein:
in response to the second feedback voltage being higher than the first reference voltage, a current passing from the output terminal through the third resistor and into the first feedback circuit increases, and
in response to the second feedback voltage being lower than the first reference voltage, the current passing from the output terminal through the third resistor and into the first feedback circuit reduces.

6. The power supply circuit as claimed in claim 1, wherein the compensation circuit is integrated into the SOC.

7. A power supply circuit providing power to a system on chip (SOC), comprising:
a power generation circuit adjusting an input voltage according to a first feedback voltage to generate an output voltage;
a first feedback circuit coupled to the power generation circuit and generating the first feedback voltage according to the output voltage;
a conducting wire coupled between the power generation circuit and the SOC to receive the output voltage, using the output voltage as a load voltage and providing the load voltage to the SOC;
a second feedback circuit coupled to the conducting wire and generating a second feedback voltage according to the load voltage; and
a compensation circuit adjusting the first feedback voltage according to the second feedback voltage and comprising:
an analog-to-digital converter converting the second feedback voltage to generate a digital signal;
a processing circuit calculating a difference value, which is the value of the difference between the digital signal and a predetermined value and outputting the difference value;
a digital-to-analog converter converting the difference value to generate 36 an analog signal; and
a resistor coupled between the digital-to-analog converter and the first feedback circuit and receiving the analog signal.

8. A power supply circuit providing power to a system on chip (SOC), comprising:
a power generation circuit adjusting an input voltage according to a first feedback voltage to generate an output voltage;
a first feedback circuit coupled to the power generation circuit and generating the first feedback voltage according to the output voltage;
a conducting wire coupled between the power generation circuit and the SOC to receive the output voltage, using the output voltage as a load voltage and providing the load voltage to the SOC;
a second feedback circuit coupled to the conducting wire and generating a second feedback voltage according to the load voltage; and
a compensation circuit adjusting the first feedback voltage according to the second feedback voltage and comprising:
an operational amplifier comprising a non-inverting input terminal, an inverting input terminal, and a first output terminal, wherein the inverting input terminal receives the second feedback voltage, and the non-inverting input terminal is coupled to a node;
an inverter comprising an input terminal and a second output terminal, wherein the input terminal is coupled to the first output terminal;
a first resistor coupled between the second output terminal and the node;
a second resistor coupled between the node and a ground terminal; and
a third resistor coupled between the second output terminal and the first feedback circuit,
wherein:
in response to the second feedback voltage being higher than a first reference voltage, the compensation circuit increases the first feedback voltage,
in response to the first feedback voltage being higher than a second reference voltage, the power generation circuit reduces the output voltage,
in response to the second feedback voltage being lower than the first reference voltage, the compensation circuit reduces the first feedback voltage, and
in response to the first feedback voltage being lower than the second reference voltage, the power generation circuit increases the output voltage.
